(19) United States
(12) Patent Application Publication
(10) Pub. No.: US 2020/0077176 A1
(43) Pub. Date: Mar. 5, 2020

(54) Earbuds With Capacitive Touch Modality

(71) Applicant: Soniphi LLC, Incline Village, NV (US)

(72) Inventors: Wayne J. Powell, Centennial, CO (US); Deric Solis, Santa Rosa, CA (US); Matthew Sanderson, Incline Village, NV (US); James McClanahan, Greenwood Village, CO (US)

(21) Appl. No.: 16/552,030

(22) Filed: Aug. 27, 2019

Related U.S. Application Data
(60) Provisional application No. 62/724,544, filed on Aug. 29, 2018.

(51) Int. Cl. H04R 1/10; H03K 17/96; H03K 17/955

(52) U.S. Cl. CPC H04R 1/1041; H04R 1/1016; H04R 2420/07; H03K 17/955; H03K 17/962

(57) ABSTRACT

An earbud that includes an array of capacitive sensors arranged on a stem extending from the earbud is disclosed. Elements of the array are connected in a bucket brigade arrangement, and can have different dimensions and/or compositions. Signals from the array of capacitive sensors are provided to a processor or microcontroller, which in turn provides instructions to a media player. The earbud can include a light source, such as a laser, that is also in communication with the controller.

This application claims the benefit U.S. Provisional Patent Application No. 62/724,544, filed on Aug. 29, 2018. These and all other referenced extrinsic materials are incorporated herein by reference in their entirety. Where a definition or use of a term in a reference that is incorporated by reference is inconsistent or contrary to the definition of that term provided herein, the definition of that term provided herein is deemed to be controlling.

### FIELD OF THE INVENTION

The field of the invention is audio control systems.

The following description includes information that may be useful in understanding the present invention. It is not an admission that any of the information provided herein is prior art or relevant to the presently claimed invention, or that any publication specifically or implicitly referenced is prior art.

Conventional portable audio systems often include a pair of headphones that are connected to a portable media player (e.g., with one or more wires). As the headphone industry has expanded, the style range of headphones from which a user may choose has increased. One popular style or configuration of headphones is known as “earbud-style” headphones (e.g., headphones designed to fit within a user's ear). Earbud-style headphones are popular among users because earbud headphones are generally small and portable. Moreover, when a user is participating in various activities, earbud headphones may cooperate better with the user's other accessories or equipment, such as helmets, ski goggles, ear protectors, beanies, and headbands.

With the increasing popularity of earbuds and the increase in advanced media playback functions available to current devices, the corresponding problem of allowing a user to effectively control media playback using a small user interface has emerged. The use of conventional buttons in small playback devices requires a high degree of targeted button presses in particular patterns. As such, conventional media playback control mechanisms are difficult to use with precision and simplicity.

U.S. Pat. No. 7,925,029, to Hollemans and Buil, describes a personal audio system that includes a touch sensitive area. Commands are provided to the device through detection of temporal patterns of contact on this touch sensitive area. Such an approach, however, requires physical contact with the device. Such contact can interfere with placement and positioning of the touch sensitive area, as such contact could displace a small device to which it is coupled. All publications identified herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

U.S. Pat. No. 10,110,987, to Yamkovoy, describes a method for controlling an audio system in which pressure changes within the ear canal of a user in response to contact with a headphone are detected. Such a method, however, relies on using a headphone that forms a tight seal with the ear or walls of the ear canal (which can cause comfort issues) and assumes that a user has properly inserted the device.

U.S. Pat. No. 10,117,012, to Saulsbury and McQueen, describes an earbud that includes proximity sensor circuitry. Among the various embodiments described are devices that use such a proximity sensor based on capacitance. A related approach is described in U.S. Pat. No. 10,334,347, to Kofman and Klemme, in which a complex capacitive sensor with an exposed trace is used to determine positioning of the earbud within an ear canal of a user. Similarly, U.S. Pat. No. 10,291,975, to Howell et al., describes wireless earbuds equipped with optical proximity sensors. Data from such sensors is used to indicate that status or position of the earbud (i.e. placed within the ear, resting within a case, covered by a protective device, etc.). Such approaches, however, do not provide control over functions of the device.

Therefore, further improvements of earbud control systems are desired. Thus, there is still a need in the art for improved physical user interfaces for earbuds.

### SUMMARY OF THE INVENTION

The inventive subject matter provides apparatus, systems and methods in which an earbud is provided with a capacitance-based proximity sensor that is utilized to provide control function to a media player that is in communication with the earbud.

One embodiment of the inventive concept is a capacitive control interface for earbuds that includes an earbud stem, a capacitive sensor coupled to the earbud stem and configured to allow control over one or more functions of the earbud, and a processor or microcontroller communicatively coupled to the capacitive sensor that has one or more program instructions (such as a fast forward instruction, a rewind instruction, a skip forward instruction, and a skip backward instruction) that are executable in response to data from the capacitive sensor. The capacitive sensor can be an array that has two or more capacitor elements, which can be arranged as a one- or two-dimensional array. In a preferred embodiment these capacitor elements are arranged as a bucket brigade circuit. Capacitor elements of such an array can differ in size and/or shape (e.g. at least one dimension) and can differ in composition from one another. In some embodiments the processor is also in communication with a light source.

Another embodiment of the inventive concept is an earbud that includes a shell having a body and a stem extending from the body, a capacitive sensor coupled to the earbud stem and configured to allow control over one or more functions of the earbud, and a processor or microcontroller communicatively coupled to the capacitive sensor that has one or more program instructions (such as a fast forward instruction, a rewind instruction, a skip forward instruction, and a skip backward instruction) that executable in response to data from the capacitive sensor. The capacitive sensor can be an array that has two or more capacitor elements, which can be arranged as a one- or two-dimensional array. In a preferred embodiment these capacitor elements are arranged as a bucket brigade circuit. Capacitor elements of such an array can differ in size and/or shape (e.g. at least one dimension) and can differ in composition from one another. In some embodiments the processor is also in communication with a light source.

Various objects, features, aspects and advantages of the inventive subject matter will become more apparent from the following detailed description of preferred embodiments, along with the accompanying drawing FIGURES in which like numerals represent like components.

### BRIEF DESCRIPTION OF THE DRAWINGS

FIG. 1: FIG. 1 schematically depicts an earbud embodiment of the inventive concept.

### DETAILED DESCRIPTION

The inventive subject matter provides apparatus, systems, and methods in which an earbud stem or shaft includes a capacitive touch sensor that provides input to a processor and serves to provide a control mechanism.

The following discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

An earbud of the inventive concept can include a housing or body that is in contact with and/or at least partially inserted into an ear of a user when in use. Such a housing can be constructed of one or more materials suitable for contact with human skin, and can have different compositions in different regions of the housing. For example, portions of the housing that are exposed when in use can be constructed of one or more rigid materials (e.g. hard plastic, metal, ceramic, etc.) whereas portions that are inserted into the ear canal can be constructed of one or more pliant materials (e.g. silicone rubber, latex, polyurethane, etc.). In some embodiments an earbud of the inventive concept can include a hook or similar projection that engages with the concha of the ear, improving stability and proper positioning of the earbud. The housing of the earbud can also support one or more control features that can be used to control earbud functions. In a preferred embodiment a portion of the body or housing can extend downwards in a stem or stalk.

Such an earbud can include a power supply (such as a battery) and one or more speakers, and is in communication with a source of audio and/or video files for playback through the earbud. Such audio and/or video files can be stored on memory within the earbud, or can be stored on memory in an external device (such as a computer, telephone, or portable audio player). In embodiments where audio and/or video files are stored in an external device the earbud can include an antenna, circuitry, and appropriate processing to support wireless communication (e.g. BlueTooth, WiFi, etc.). Alternatively or in addition to such wireless circuitry, and earbud of the inventive concept can include a port that supports a wired connection. Earbuds of the inventive concept can also include an antenna and associated circuitry to support wireless charging of an onboard power supply, for example by magnetic induction.

In some embodiments of the inventive concept an array of capacitive switches (such as a bucket brigade array) is positioned on or within a stem or shaft extending from a main body of an earbud. Such an array can be linear (i.e. having a single column or row of capacitor elements) or two dimensional (i.e. having a plurality of capacitor elements arranged across both length and width). In such an array capacitor elements can be identical. Alternatively, such an array can include two or more capacitor elements having different physical and/or performance characteristics. In such an embodiment, for example, an array of capacitor elements can be provided that have a variety of sizes, dimensions, and/or material compositions. These advantageously provide such an array with a range of sensitivity to externally applied electric fields (such as those generated by proximity to or contact with a user's finger). While the array of capacitive switches is preferentially positioned on or in a stem extended from the body of the earbud, in some embodiments all or a portion of the array can be positioned on or in the body of the earbud (i.e. the portion of the earbud in contact with the concha of the ear when inserted).

In some embodiments the earbud can utilize sensor data obtained from the array of capacitive switches, other sensing elements, or a combination of these to functionally isolate specified capacitor elements from the array. This provides a mechanism for adjusting the sensitivity of the array to suit the position or local environment of the earbud.

Data from the array of capacitive switches is generated by contact with and/or proximity to the users skin surface (typically a portion of the users finger). This allows a user to activate a microcontroller input-output (I/O) interface that is in communication with the capacitor array. In preferred embodiments, activating the microcontroller I/O interface is accomplished by contacting the array of capacitive switches (or coming into sufficient proximity) to cause one or more electrical signals to be sent to the microcontroller.

It is further contemplated that the RC constant (τ) is altered by user skin surface proximity to the array (e.g, through physical contact or close proximity) and can affect the switching of the input ports on a processor (such as a microcontroller). This switching can generate commands from the processor to an audio and/or video player. Examples of suitable commands include initiating playback of a stored file, pausing playback, terminating playback of a first file and initiating playback of a second file from a playlist, initiating receipt of a voice command, initiating a telephone call, initiating a text message, and so on. Additionally, it is also contemplated that devices of the inventive concept can produce a frequency shift in an oscillator circuit to activate a processor coupled to a microcontroller I/O interface.

It should be appreciated that such a bucket brigade arrangement of a capacitor array advantageously allows for different capacities or frequencies to provide data to processor and/or microcontroller, thereby enhancing the sensitivity and range of a control system utilizing same.

In a preferred embodiment the array of capacitive switches is paired with a light source (such as an LED or laser) that is controlled by a processor and/or microcontroller that receives data from the array. Data provided from the array of capacitive switches can be utilized by the processor and/or microcontroller in determining output that is provided to the light source.

In such embodiments the light source can be positioned to direct output light towards the lower portion or bottom of the stem or shaft of the earbud. This lower portion or end can be fitted with a cap, which can be transparent, translucent, or opaque. Light emitted through the cap can be used for a variety of purposes. For example, such emitted light provides information regarding the status of the earbud (battery status, wireless connectivity status, etc.). Alternatively, such emitted light can be directed so as to be perceived (either consciously or subconsciously) by the user, so as to enhance their listening experience. In some embodiments the interior of such a cap can be reflective, directing at least a portion of the light emitted by the light source to other components of the earbud. In such embodiments the reflected light can provide communication, data, or instruction transmission between the microprocessor and the components.

As noted above, the capacitive switch modality is installed vertically on the shaft of the earbud assembly. In preferred embodiments, the earbuds comprise a main body portion with an extended curvature configuration. In one example, the earbuds include a primary body that is contact with concha of the ear and can be at least partially inserted into the ear canal when in use. Such a body can include speaker housing separated into a divided group of isobaric sound chambers and an extension that couples the isobaric sound chambers via a transmission line to form a waveguide between the speaker housing and the extension.

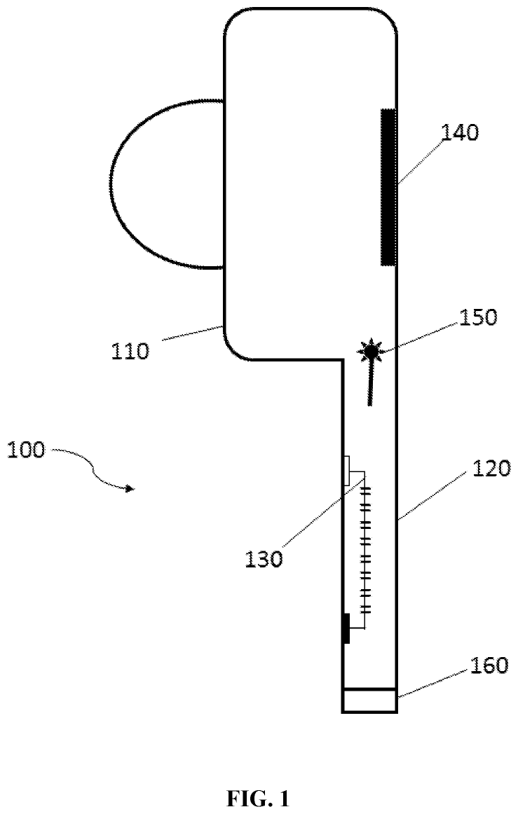

An example of an earbud of the inventive concept (100) is shown in FIG. 1. As shown, the earbud has a housing (110) from which extends an elongated shaft (120). A capacitive sensor array (130) is positioned within the shaft, where it is readily accessible for contact by a user's finger. In a preferred embodiment the capacitive sensor array includes a series of capacitors arranged as a “bucket brigade”. Members of this series of capacitors can be of different sizes, compositions, and/or configurations, such that the capacitor array can be responsive to a wide range of contact or near-contact events (e.g. contact or near contact with a finger of a user). Such near-contact events provide sufficient proximity to generate a response from the array without actual contact with the earbud. The capacitive sensor array (130) is in communication with and provides input to a microprocessor (140), for example in the form of one or more electronic pulses, change in RC time constant (i.e. τ) and/or frequency, in response to proximity of an electrical field (e.g. due to contact or near contact with a user's finger). In some embodiments the controller can be enclosed within the housing.

Input from the capacitive sensor array is utilized by the processor to generate outputs that control various functions of the earbud. For example, data from the capacitive sensor array can be used to start playing of an audio and/or video file, pause playing of an audio and/or video file, skip or select and audio and/or video file, repeat an audio and/or video file, change volume, and/or select an audio filter.

In some embodiments data from the capacitive sensor array (130) is by the processor (140) to provide outputs to a light source (150) within the earbud. Suitable light sources include one or more LEDs, lasers, and/or solid state lasers. Such light sources can be positioned to direct their output towards a cap (160) positioned at or near the terminus of the stem (120). Such a cap can be transparent, translucent, or opaque. In some embodiments the cap can have a reflective internal surface that redirects output from the light source within the earbud, where it can interact with other earbud components. In some of such embodiments the use of a reflective cap provides a desired time delay for one or more emitted pulses of light. The output of the light source (150) can be controlled by the processor (140) to provide a variety of functions, including providing a visual indication of earbud status, providing a visual indication of a received command gesture from a user, and/or enhancement of the user's listening experience (for example, in providing consciously or subconsciously perceived lighting effects).

Various objects, features, aspects and advantages of the inventive subject matter will become more apparent from the following detailed description of preferred embodiments, along with the accompanying drawing FIGURES in which like numerals represent like components.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refer to at least one of something selected from the group consisting of A, B, C . . . and N, the text should be interpreted as requiring only one element from the group, not A plus N, or B plus N, etc.

What is claimed is:

1. A capacitive control interface for earbuds, comprising:
an earbud stem;
a capacitive sensor, wherein the capacitive sensor is coupled to the earbud stem and configured to allow control over one or more functions of the earbuds; and
a processor or microcontroller communicatively coupled to the capacitive sensor, wherein the processor or microcontroller comprises one or more program instructions executable in response to data from the capacitive sensor.

2. The capacitive control interface of claim 1, wherein the capacitive sensor comprises an array comprising a plurality of capacitor elements.

3. The capacitive control interface of claim 2, wherein the array is a one dimensional array.

4. The capacitive control interface of claim 2, wherein the array is a two dimensional array.

5. The capacitive control interface of claim 2, wherein the plurality of capacitor elements is arranged as a bucket brigade circuit.

6. The capacitive control interface of claim 2, wherein the array comprises a first capacitor element and a second capacitor element, wherein the first capacitor element and the second capacitor element differ in at least one of dimension and composition.

7. The capacitive control interface of claim 1, wherein the processor is communicatively coupled to a light source.

8. The control interface of claim 1, wherein the one or more program instructions are selected from the group consisting of: a fast forward instruction, a rewind instruction, a skip forward instruction, and a skip backward instruction.

9. An earbud, comprising:
a shell comprising a body and a stem extending from the body;
a capacitive sensor, wherein the capacitive sensor is coupled to the stem; and
a processor or microcontroller communicatively coupled to the capacitive sensor, wherein the processor or microcontroller comprises one or more program instructions executable in response to data from the capacitive sensor.

10. The earbud of claim 9, wherein the capacitive sensor comprises an array comprising a plurality of capacitor elements.

11. The earbud of claim 10, wherein the array is a one dimensional array.

12. The earbud of claim 10, wherein the array is a two dimensional array.

13. The earbud of claim 10, wherein the plurality of capacitor elements is arranged as a bucket brigade circuit.

14. The earbud of claim 10, wherein the array comprises a first capacitor element and a second capacitor element, wherein the first capacitor element and the second capacitor element differ in at least one of dimension and composition.

15. The earbud of claim 9, wherein the processor is communicatively coupled to a light source.

16. The earbud of claim 9, wherein the one or more program instructions are selected from the group consisting of: a fast forward instruction, a rewind instruction, a skip forward instruction, and a skip backward instruction.
